(19) United States
(12) Patent Application Publication
(10) Pub. No.: US 2026/0266873 A1
(43) Pub. Date: Sep. 10, 2026

(54) PROBE CARD DEVICE

(71) Applicant: Silicon Future Manufacturing Company Ltd., Hsinchu City (TW)

(72) Inventors: Wen-Tsung Sung, Hsinchu City (TW); Chia-Hsiang Yu, Hsinchu City (TW); You-Chen Lin, Hsinchu City (TW); Yu-Chien Chen, Hsinchu City (TW); Cheng-Chun Wu, Hsinchu City (TW); Chih-Wei Wei, Hsinchu City (TW)

(21) Appl. No.: 19/278,482

(22) Filed: Jul. 23, 2025

(30) Foreign Application Priority Data
Mar. 10, 2025 (TW) 114108699

(51) Int. Cl. G01R 1/073

(52) U.S. Cl. CPC G01R 1/07342

(57) ABSTRACT

A probe card device includes: a test circuit board, a space transformer electrically connected to the test circuit board, and a probe head electrically connected to the space transformer. The probe head includes: an upper guide plate having first through holes, a lower guide plate having second through holes, and probes. Each probe includes a needle body having a first end and a second end opposite to each other, a needle tail connected to the first end and disposed on the upper guide plate, and a needle head connected to the second end. The needle body sequentially passes through the first through hole and the second through hole. The needle body has a first side and a second side connected to each other on a cross-section parallel to the lower guide plate, wherein a length of the first side is less than a length of the second side.

### CROSS REFERENCE TO RELATED APPLICATION

This application claims the priority benefit of Taiwan Patent Application No. 114108699, filed on Mar. 10, 2025. The entirety of the mentioned above patent application is hereby incorporated by reference herein and made a part of this specification.

### BACKGROUND OF THE INVENTION

### Field of the Invention

The present invention relates to a probe card device. Specifically, the present invention relates to a probe card device capable of improving the alignment accuracy of probe during the testing process.

### Description of the Prior Art

In current semiconductor manufacturing processes, prior to wafer dicing and packaging, electrical testing of the objects to be tested (such as dies) is conducted by using a probe card, thereby ensuring yield, eliminating defective products, and reducing cost. Current probe cards include cantilever probe cards and vertical probe cards. According to the manufacturing methods, conventional vertical probes can be categorized into micro-electromechanical system (MEMS) probes, cobra probes, and wire probes. Among them, both cobra probes and wire probes have circular shape of the needle and the hole on the guide plate, wherein the holes are mostly fabricated by mechanical drilling. In contrast, MEMS probes have a nearly square shape of the needle and the hole on the guide plate, wherein the holes are mostly fabricated by laser drilling.

Compared to conventional probe cards, MEMS probe cards provide increased signal transmission rates and enable a higher probe density, thereby improving testing efficiency. The cross-sectional dimensions of current MEMS probes (i.e., the cross-section of the needle body of the probe) generally range from 22 μm×22 μm to 50 μm×50 μm, corresponding to the spacing or size of the metal contact points (such as metal pads or gold bumps) on the objects to be tested. When the spacing between the metal contact points is relatively large, MEMS probes with larger cross-section (for example, 50 μm×50 μm) can be used to reduce testing costs without compromising alignment accuracy. However, when the spacing is relatively small, MEMS probes with smaller cross-section (for example, below 30 μm×30 μm) are required. In such cases, misalignment between the probe and the hole on the guide plate may occur, such as unintended probe rotation, resulting in inaccurate contact with the corresponding metal contact point of the object to be tested. Therefore, there is a need for a probe card device to improve the deficiencies of the prior art.

### SUMMARY OF THE INVENTION

To solve the above problems, an embodiment of the present invention provides a probe card device including a test circuit board, a space transformer, and a probe head. The space transformer is electrically connected to the test circuit board. The probe head is electrically connected to the space transformer. The probe head includes an upper guide plate, a lower guide plate, and a plurality of probes. The upper guide plate has a plurality of first through holes. The lower guide plate is disposed corresponding to the upper guide plate and having a plurality of second through holes. The plurality of probes are mounted on the upper guide plate. Each of the plurality of probes includes a needle body, a needle tail, and a needle head. The needle body sequentially passes through a corresponding one of the plurality of first through holes and a corresponding one of the plurality of second through holes. The needle body has a first end and a second end opposite to the first end. The needle body further has a first side and a second side connected to the first side on a cross-section parallel to the lower guide plate, wherein a length of the first side is less than a length of the second side. The needle tail is connected to the first end and disposed on the upper guide plate. The needle head is connected to the second end.

According to the probe card device of the present invention, since the length of the first side in a cross-section of the needle body parallel to the lower guide plate is less than the length of the second side in the said cross-section, the needle bodies can be tightly confined within the second through holes when passing through the through holes of the lower guide plate, thereby reducing displacement and improving alignment between the probes and the metal pads on the object to be tested during testing process.

### BRIEF DESCRIPTION OF THE DRAWINGS

FIG. 1 is a schematic diagram of the probe card device according to an embodiment of the present invention.

FIG. 2 is a 3D structural diagram of the probe head in the probe card device according to the embodiment shown in FIG. 1.

FIG. 3 is a schematic diagram of the probe in the probe card device according to the embodiment shown in FIG. 2.

FIG. 4 is a 3D structural diagram of the probes and the lower guide plate in the probe card device according to the embodiment shown in FIG. 2.

FIG. 5 is a cross-sectional diagram of the probes in the probe card device according to the embodiment shown in FIG. 4.

FIG. 6 is a schematic diagram of a portion of the upper guide plate in the probe card device according to the embodiment shown in FIG. 2.

FIG. 7 is a schematic diagram of a portion of the lower guide plate in the probe card device according to the embodiment shown in FIG. 2.

FIG. 8 is a side view of the second end of the probe in the probe card device according to the embodiment shown in FIG. 2.

FIG. 9 is a 3D structural diagram of the probe head in the probe card device according to another embodiment of the present invention.

FIG. 10 is a 3D structural diagram of the probes and the lower guide plate in the probe card device according to the embodiment shown in FIG. 9.

FIG. 11 is a cross-sectional diagram of the probes in the probe card device according to the embodiment shown in FIG. 9.

FIG. 12 is a top view of the second end of the probes in the probe card device according to the embodiment shown in FIG. 9.

FIG. 13 is a schematic diagram of a portion of the upper guide plate in the probe card device according to the embodiment shown in FIG. 9.

FIG. 14 is a schematic diagram of a portion of the lower guide plate in the probe card device according to the embodiment shown in FIG. 9.

### DETAILED DESCRIPTION OF THE INVENTION

Various embodiments will be described below, and a person having ordinary skill in the art can easily understand the spirits and principles of the present invention referring to this specification accompanied by the drawings. However, although some particular embodiments will be specifically illustrated herein, these embodiments are only exemplary, and are not regarded as limiting or exhaustive in all respects. Therefore, for a person having ordinary skill in the art, various changes and modifications to the present invention should be obvious and can be easily achieved without departing from the spirits and principles of the present invention.

In various embodiments of the present invention, the terms “above”, “below”, “left”, “right”, “front”, or “back” are used to describe the relationship between one component and another. These terms are only used to illustrate the orientation as shown in the figures and do not limit the actual position. The relative orientation or positioning of the components described in the specification is not restricted by the flipping of the device in the drawings. For example, if a device in an attached figure is flipped upside down, an element described as being “below” another element will be “above” that element.

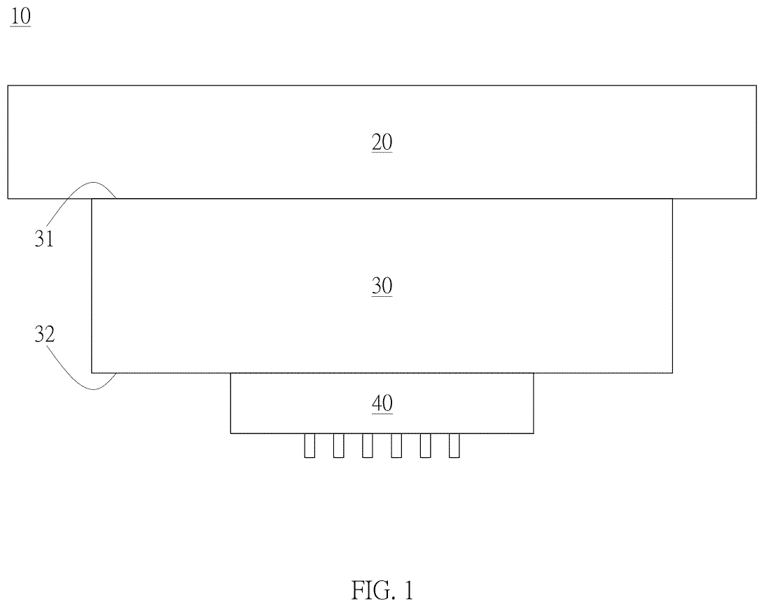

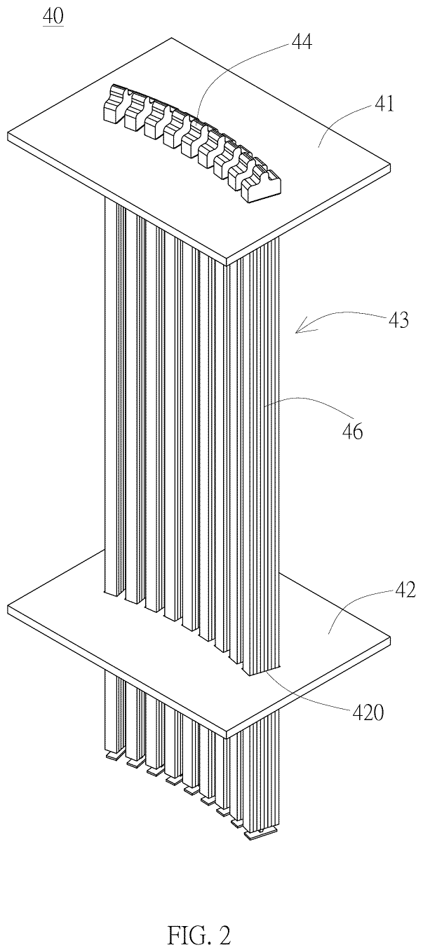

FIG. 1 is a schematic diagram of the probe card device 10 according to an embodiment of the present invention. Referring to FIG. 1, the probe card device 10 of this embodiment includes a test circuit board 20, a space transformer 30, and a probe head 40. For the convenience of explaining the structure of the probe card device 10, those elements are not drawn to actual scale. For example, the thickness of the test circuit board 20 may be greater than the thickness of the space transformer 30 in reality. The space transformer 30 is electrically connected to the test circuit board 20. The probe head 40 is electrically connected to the space transformer 30. The test circuit board 20 can transmit the test signal through the space transformer 30 to the probe head 40. The test result signal can also be transmitted from the probe head 40 through the space transformer 30 to the test circuit board 20. For example, the test circuit board 20 can be a printed circuit board. The test circuit board 20 can provide the test signal or receive the test result signal from the probe head 40. The space transformer 30 has a first surface 31 and a second surface 32 opposite to the first surface 31. The first surface 31 has a plurality of contact points for electrically connecting the plurality of connection points on the test circuit board 20. The second surface 32 also has a plurality of contact points for electrically connecting to the probe head 40. Since the arrangement of the connection points on the test circuit board 20 is different from the arrangement of the probes 43 of the probe head 40 (as shown in FIG. 2), the space transformer 30 is used to transform the spatial configuration of internal wiring, facilitating the test circuit board 20 to be electrically connected to the probes 43 of the probe head 40.

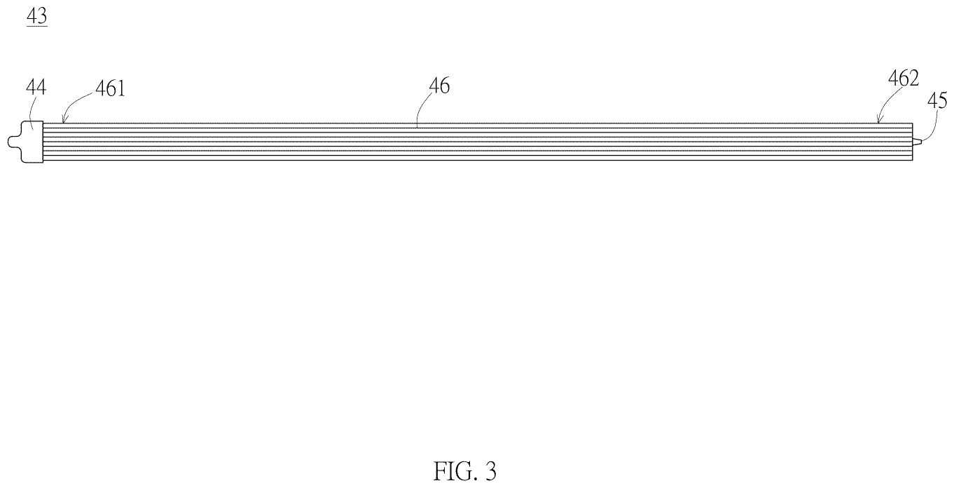

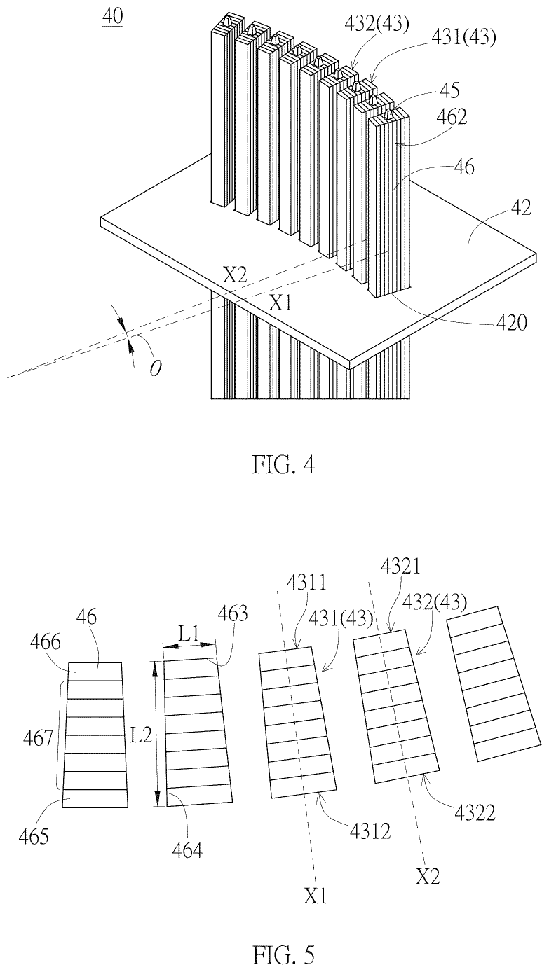

FIG. 2 is a 3D structural diagram of the probe head 40 in the probe card device according to the embodiment shown in FIG. 1. FIG. 3 is a schematic diagram of the probe in the probe card device according to the embodiment shown in FIG. 2. Referring to FIGS. 1 to 3, the probe head 40 includes an upper guide plate 41, a lower guide plate 42, and a plurality of probes 43. The upper guide plate 41 may, for example, have a plurality of first through holes 410 (as shown in FIG. 6) for the probes 43 to pass through. The lower guide plate 42 is positioned corresponding to the upper guide plate 41 and has a plurality of second through holes 420 (as shown in FIGS. 4 and 7) for the probes 43 to pass through. The probes 43 are mounted on the upper guide plate 41, wherein each probe 43 includes a needle body 46, a needle tail 44, and a needle head 45. The needle body 46 sequentially passes through a corresponding first through hole 410 of the upper guide plate 41 and a corresponding second through hole 420 of the lower guide plate 42. The needle body 46 includes a first end 461 and a second end 462 opposite to the first end 461. The needle tail 44 is connected to the first end 461 to position and secure the probe 43 onto the upper guide plate 41, allowing the probes 43 to be electrically connected to a plurality of contact points on the second surface 32 of the space transformer 30. The needle head 45 is connected to the second end 462. In this embodiment, the upper guide plate 41 may, for example, be parallel to the lower guide plate 42, and the probes 43 are parallel to each other along the direction perpendicular to the lower guide plate 42 to avoid interference between each other.

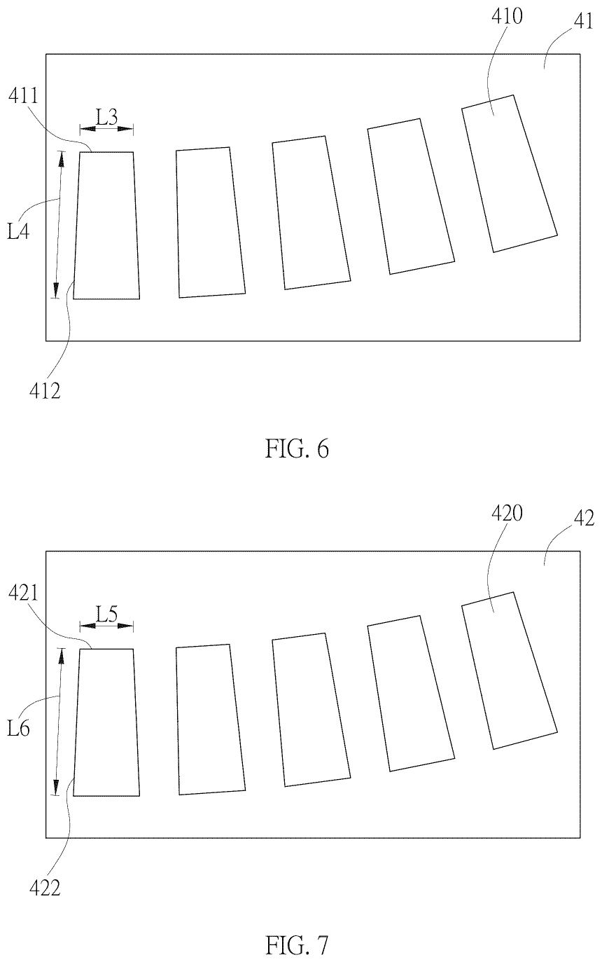

FIG. 4 is a 3D structural diagram of the probes and the lower guide plate in the probe card device according to the embodiment shown in FIG. 2. FIG. 5 is a cross-sectional diagram of the probes in the probe card device according to the embodiment shown in FIG. 4. Referring to FIGS. 2 to 5, the probes 43 are arranged parallel to each other with gaps therebetween. The second end 462 of each needle body 46 passes through a corresponding second through hole 420 of the lower guide plate 42. In this embodiment, the needle body 46 of the probe 43 has a trapezoidal cross-section on a plane parallel to the lower guide plate 42, but not limited thereto. Preferably, in another embodiment, the needle body 46 may have a rectangular cross-section on a plane parallel to the lower guide plate 42. The cross-section of the needle body 46 on the plane parallel to the lower guide plate 42 has a first side 463 and a second side 464 connected to the first side 463, wherein the length L1 of the first side 463 is less than the length L2 of the second side 464. Therefore, by virtue of the configuration of the first through holes 410 and the second through holes 420 (described in the following text), the needle body 46 can be tightly confined within the first through hole 410 and the second through hole 420, thereby reducing displacement and improving the needle alignment between the probes 43 and the metal pads on the object to be tested during testing process. Furthermore, compared to conventional MEMS probe cards, the probe card device of the present invention is capable of testing objects with smaller metal pad spacings. For example, the length L1 may be 18 μm, and the length L2 may be 30 μm.

Referring to FIGS. 4 and 5, the plurality of probes 43 may, for example, include a first probe 431 and a second probe 432 adjacent to the first probe 431. The cross-section of the needle body 46 of the first probe 431 on a plane parallel to the lower guide plate 42 has a third end 4311 and a fourth end 4312 opposite to the third end 4311, wherein the third end 4311 may, for example, be parallel to the fourth end 4312. The cross-section of the needle body 46 of the second probe 432 on a plane parallel to the lower guide plate 42 has a fifth end 4321 and a sixth end 4322 opposite to the fifth end 4321. The connection line X1 connecting the third end 4311 and the fourth end 4312 and the connection line X2 connecting the fifth end 4321 and the sixth end 4322 form an acute angle θ therebetween. That is, the connection line X1 connecting the third end 4311 and the fourth end 4312 is not parallel to the connection line X2 connecting the fifth end 4321 and the sixth end 4322. Therefore, the probes 43 of the probe card device 10 can align with the corresponding metal pads (pads or bumps made of metal materials such as gold, not shown in the figures) on the object to be tested, such as the Chip On Plastic (COP), through the first through holes 410 and the second through holes 420.

FIG. 6 is a schematic diagram of a portion of the upper guide plate in the probe card device according to the embodiment shown in FIG. 2. FIG. 7 is a structural diagram of a portion of the lower guide plate in the probe card device according to the embodiment shown in FIG. 2. Referring to FIGS. 2 to 7, the upper guide plate 41 may, for example, have a plurality of first through holes 410, wherein the first through hole 410 has a third side 411 and a fourth side 412 connected to the third side 411, and the length L3 of the third side 411 is less than the length L4 of the fourth side 412. In this embodiment, the first through hole 410 may, for example, have a trapezoidal shape, but not limited thereto. Preferably, in another embodiment, the first through hole 410 may have a rectangular shape. In addition, the lower guide plate 42 may, for example, have a plurality of second through holes 420, wherein the second through hole 420 has a fifth side 421 and a sixth side 422 connected to the fifth side 421, and the length L5 of the fifth side 421 is less than the length L6 of the sixth side 422. In this embodiment, the second through hole 420 may, for example, have a trapezoidal shape, but not limited thereto. Preferably, in another embodiment, the second through hole 420 may have a rectangular shape. In addition, the number of the first through holes 410 is equal to the number of the second through holes 420. Each first through hole 410 respectively corresponds to one second through hole 420, facilitating the probes 43 which sequentially pass through the first through holes 410 and the second through holes 420 to contact the corresponding metal pads on the object to be tested, such as the COP (not shown in the figures). For example, the length L3 and the length L5 may be 20 μm, and the length L4 and the length L6 may be 40 μm.

Referring to FIGS. 2 to 7, the positions of the first through holes 410 on the upper guide plate 41 and the positions of the second through holes 420 on the lower guide plate 42 may, for example, correspond to the positions of the metal pads on the object to be tested, thereby guiding the probes 43 into alignment. When the needle body 46 of the probe 43 sequentially passes through the first through hole 410 and the second through hole 420, the third side 411 of the first through hole 410 and the fifth side 421 of the second through hole 420 align with the first side 463 of the needle body 46, and the fourth side 412 of the first through hole 410 and the sixth side 422 of the second through hole 420 align with the second side 464 of the needle body 46. That is, the longer side of the needle body 46 faces the longer side of the first through hole 410 and the longer side of the second through hole 420, and the shorter side of the needle body 46 faces the shorter side of the first through hole 410 and the shorter side of the second through hole 420. Compared to the square probes and holes of the guide plate of conventional probe cards, this embodiment provides the needle body 46 having the length L1 of the first side 463 close to the length L3 of the third side 411 of the first through hole 410 and the length L5 of the fifth side 421 of the second through hole 420. Therefore, the needle body 46 can be tightly confined within the first through hole 410 and the second through hole 420 to reduce displacement, improving reliability during the testing process using the probe card device.

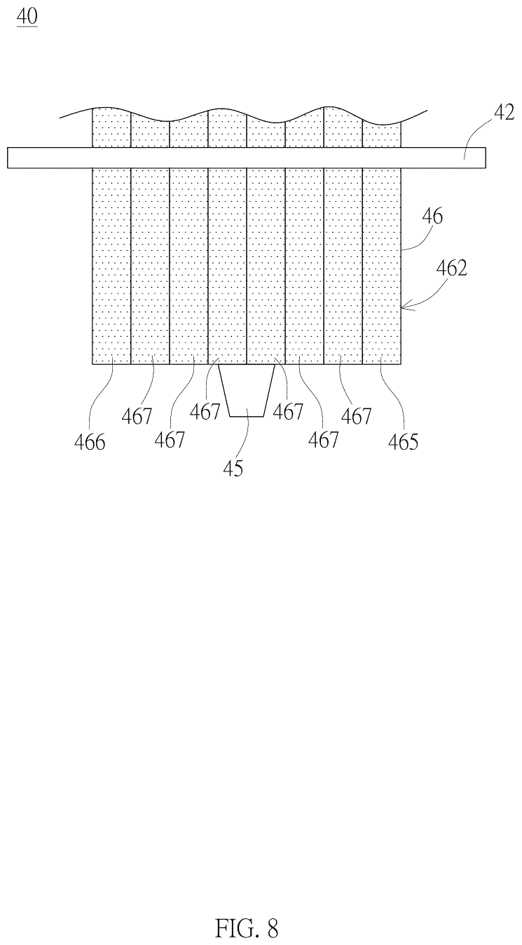

FIG. 8 is a side view of the second end of the probe in the probe card device according to the embodiment shown in FIG. 2. Referring to FIG. 2 to FIG. 8, the needle body 46 of the probe 43 is fabricated by using MEMS techniques, which is fabricated layer by layer through processes such as electroplating, photolithography, and chemical vapor deposition to define the shape. For example, a copper layer followed by a palladium-cobalt layer may be sequentially deposited. In more detail, the needle body 46 includes a bottom layer 465, a top layer 466 opposite to the bottom layer 465, and a plurality of middle layers 467, wherein the middle layers 467 are disposed between the bottom layer 465 and the top layer 466. As shown in FIGS. 5 and 8, the quantity of the middle layers 467 may be six layers, but not limited thereto. The quantity of the middle layers 467 can be less than five layers or more than seven layers. In addition, as shown in FIGS. 4 and 8, the needle head 45 is connected to the second end 462, and the needle head 45 is positioned on the middle layer 467 to electrically contact the corresponding metal pad of the object to be tested. However, in another embodiment, the needle head 45 may be positioned between the bottom layer 465 and the middle layer 467 or between the top layer 466 and the middle layer 467, which is not limited in the present invention.

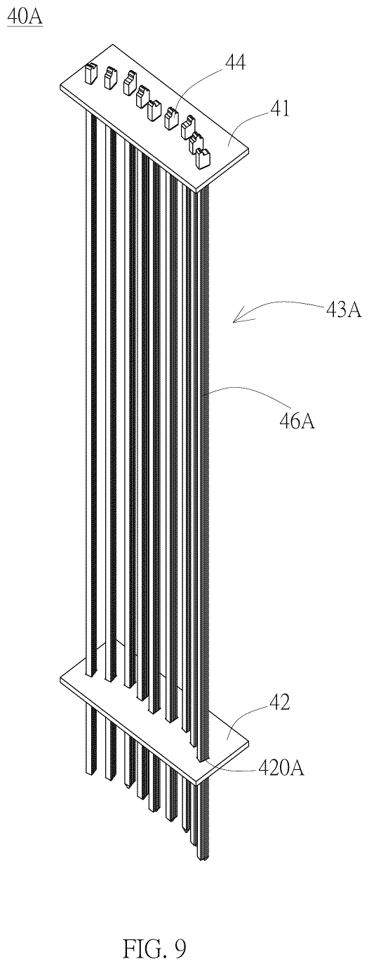

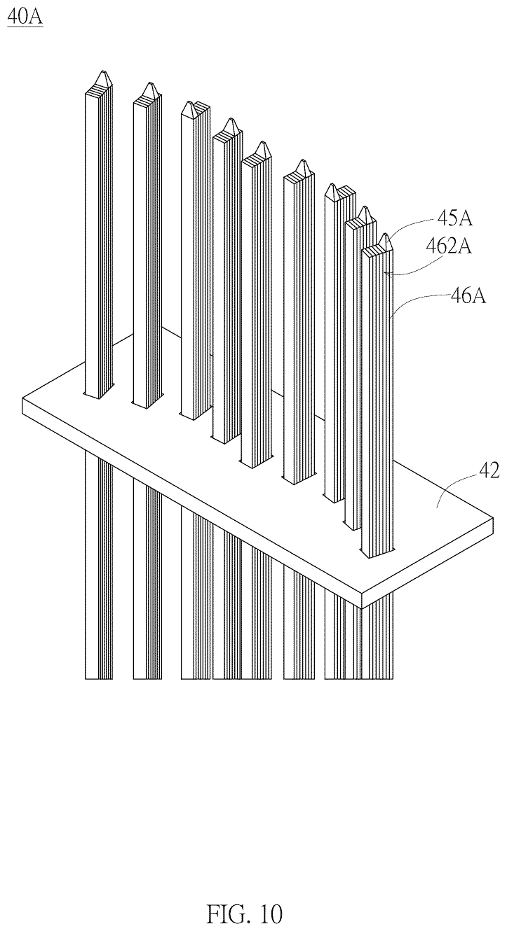

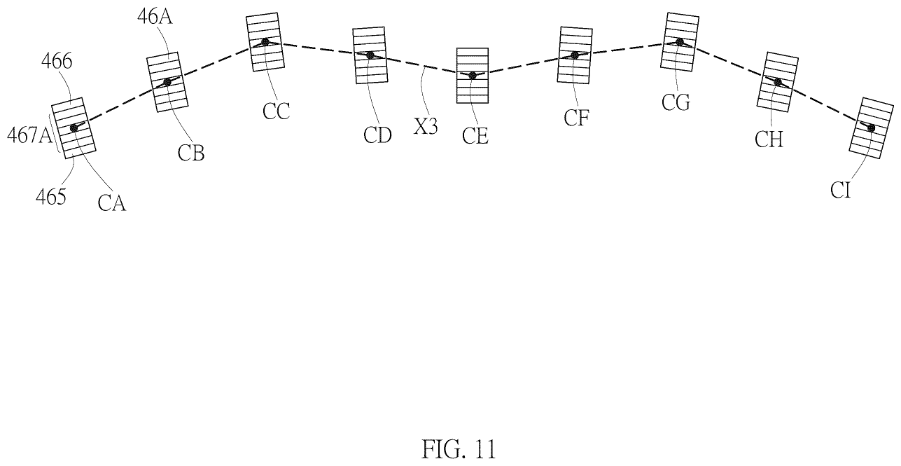

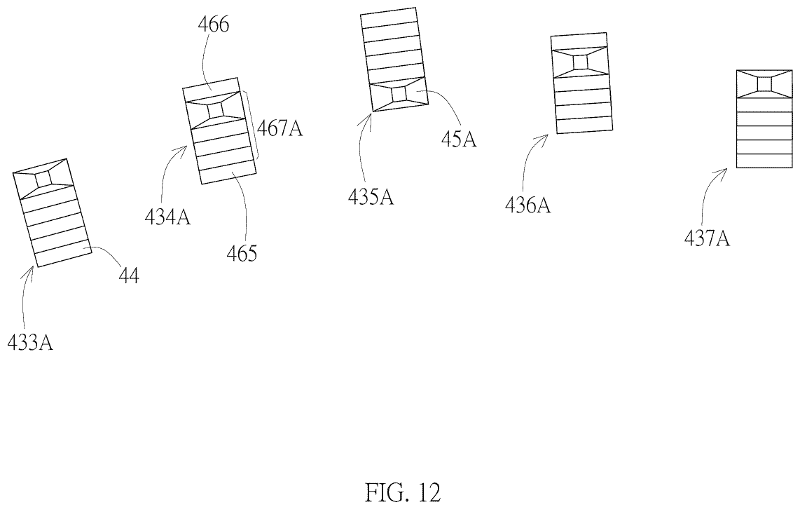

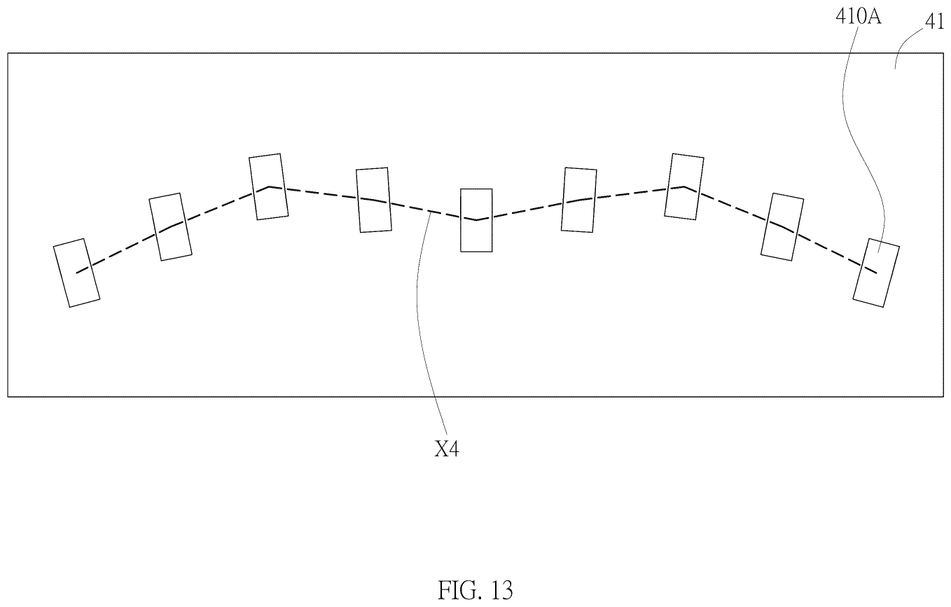

FIG. 9 is a 3D structural diagram of the probe head in the probe card device according to another embodiment of the present invention. FIG. 10 is a 3D structural diagram of the probes and the lower guide plate in the probe card device according to the embodiment shown in FIG. 9. FIG. 11 is a cross-sectional diagram of the probes in the probe card device according to the embodiment shown in FIG. 9. FIG. 12 is a top view diagram of the second end of the probes in the probe card device according to the embodiment shown in FIG. 9. Referring to FIGS. 9 to 12, the probe head 40A in this embodiment can be applied in the probe card device 10 (referring to FIG. 1), wherein the probe head 40A is similar to the probe head 40 (referring to FIGS. 1 to 8) in the previous embodiments. The same components are labeled with the same reference sign, and will not be elaborated further. The needle body 46A of each probe 43A in the probe head 40A has a central point on a cross-section parallel to the lower guide plate 42. The difference between the probe head 40A and the probe head 40 is that a polyline connecting the central points of the needle bodies 46A forms a M-shape, while a polyline connecting the central points of the needle bodies 46 forms an arc (referring to FIGS. 4 and 5). In more detail, FIG. 11 schematically shows the cross-sections of nine needle bodies 46A of the probes 43A parallel to the lower guide plate 42. However, the present invention is not limited thereto. Practically, the probe head 40A may have a greater number of probes 43A. In addition, the cross-sections of the needle body 46A of the probes 43A respectively have the central points CA, CB, CC, CD, CE, CF, CG, CH, and CI, wherein the polyline X3 connecting the central points CA~CI is presented in a M-shape. Therefore, the probes 43A can align with the corresponding metal pads on the object to be tested, such as COP, in a more precise manner.

In addition, referring to FIGS. 9 to 12, the needle body 46A includes a bottom layer 465, a top layer 466 opposite to the bottom layer 465, and a plurality of middle layers 467A, wherein the middle layers 467A are disposed between the bottom layer 465 and the top layer 466. Due to different sizes and configurations of the metal pads on the object to be tested, the quantity of the middle layers may vary between different embodiments. For example, in the embodiment shown in FIG. 8, the quantity of the middle layers 467 is six layers, while in the embodiment shown in FIG. 9~12, the quantity of the middle layers 467A is five layers. Referring to FIG. 12, the position of the needle heads 45A of the probes 43A can be different. For example, the probes 43A in this embodiment may, for example, include a third probe 433A, a fourth probe 434A, a fifth probe 435A, a sixth probe 436A, and a seventh probe 437A arranged adjacent to each other without contact. The needle head 45A of the third probe 433A is positioned on the top layer 466 and the adjacent middle layer 467A; the needle head 45A of the fourth probe 434A is positioned on two adjacent middle layers 467A; the needle head 45A of the fifth probe 435A is positioned on the bottom layer 465 and the adjacent middle layer 467A; the needle head 45A of the sixth probe 436A is positioned on two adjacent middle layers 467A; the needle head 45A of the seventh probe 437A is positioned on the top layer 466 and the adjacent middle layer 467A. Therefore, the probes 43A can align with the corresponding metal pads on the object to be tested, such as the COP, through the first through holes 410A and the second through holes 420A. In other embodiments, the needle heads 45A on the probes 43A may be arranged in various configurations depending on the object to be tested.

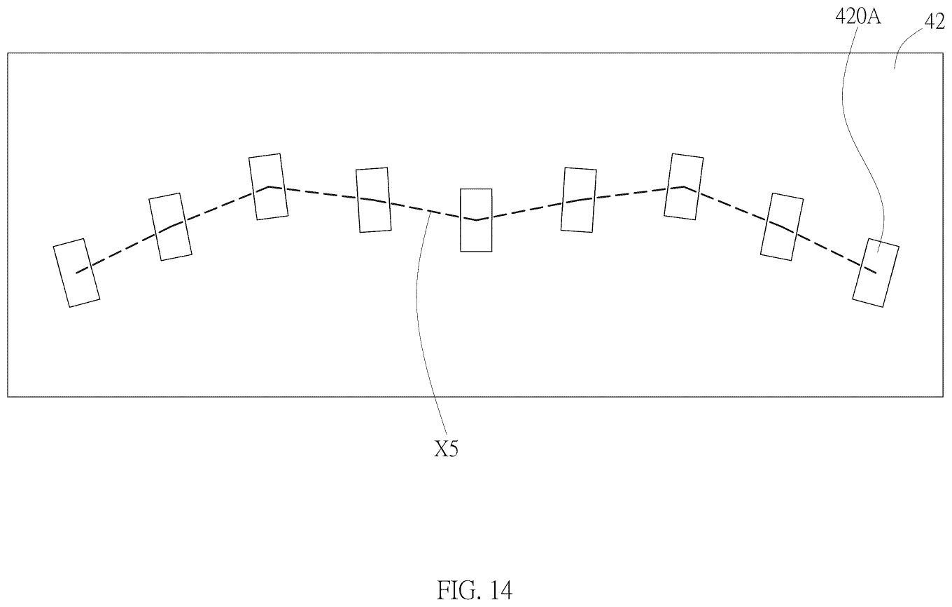

FIG. 13 is a schematic diagram of a portion of the upper guide plate in the probe card device according to the embodiment shown in FIG. 9. FIG. 14 is a schematic diagram of a portion of the lower guide plate in the probe card device according to the embodiment shown in FIG. 9. Referring to FIGS. 9 to 14, the upper guide plate 41 may, for example, have a plurality of first through holes 410A (as shown in FIG. 13) for the probes 43A to pass through. The lower guide plate 42 is positioned corresponding to the upper guide plate 41 and has a plurality of second through holes 420A (as shown in FIG. 14) for the probes 43A to pass through. The probes 43A are mounted on the upper guide plate 41. The needle body 46A sequentially passes through a corresponding first through hole 410A of the upper guide plate 41 and a corresponding second through hole 420A of the lower guide plate 42, wherein the upper guide plate 41 is parallel to the lower guide plate 42, and the probes 43A are parallel to each other along the direction perpendicular to the lower guide plate 42 to avoid interference between each other. In addition, the arrangement and rotation angles of the first through holes 410A on the upper guide plate 41 are in correspondence with the probes 43A, and the arrangement and rotation angles of the second through holes 420A on the lower guide plate 42 are also in correspondence with the probes 43A. For example, the polyline X4 connecting the central points of the first through holes 410A is presented in a M-shape corresponding to the arrangement of the probes 43A, and the polyline X5 connecting the central points of the second through holes 420A is also presented in a M-shape corresponding to the arrangement of the probes 43A, allowing the probes 43A to align with the corresponding metal pads on the object to be tested in a more precise manner.

In summary, in the probe card device of the present invention, since the length of the first side in a cross-section of the needle body parallel to the lower guide plate is less than the length of the second side in the said cross-section, the needle body can be tightly confined within the through holes when passing through the through hole of the lower guide plate, thereby reducing displacement and improving the alignment between the probes and the metal pads on the object to be tested during testing process.

The present invention has been illustrated by the above embodiments. However, the above embodiments are merely examples of the implementation of the invention. It should be noted that the disclosed embodiments do not limit the scope of the present invention. On the contrary, modifications and equivalent arrangements within the spirit and scope of the claims in the patent application are included within the scope of the present invention.

What is claimed is:

1. A probe card device, comprising:
a test circuit board;
a space transformer electrically connected to the test circuit board; and
a probe head electrically connected to the space transformer, the probe head comprising:
an upper guide plate having a plurality of first through holes;
a lower guide plate disposed corresponding to the upper guide plate and having a plurality of second through holes; and
a plurality of probes mounted on the upper guide plate, wherein each of the plurality of probes comprises:
a needle body sequentially passing through a corresponding one of the plurality of first through holes and a corresponding one of the plurality of second through holes, wherein the needle body has a first end and a second end opposite to the first end, the needle body further has a first side and a second side connected to the first side on a cross-section parallel to the lower guide plate, and a length of the first side is less than a length of the second side;
a needle tail connected to the first end and disposed on the upper guide plate; and
a needle head connected to the second end.

2. The probe card device of claim 1, wherein each of the plurality of first through holes has a third side and a fourth side connected to the third side, and a length of the third side is less than a length of the fourth side.

3. The probe card device of claim 1, wherein each of the plurality of second through holes has a fifth side and a sixth side connected to the fifth side, and a length of the fifth side is less than a length of the sixth side.

4. The probe card device of claim 1, wherein a number of the plurality of first through holes is equal to a number of the plurality of second through holes.

5. The probe card device of claim 1, wherein the plurality of probes comprise a first probe and a second probe disposed adjacent to the first probe, the needle body of the first probe comprises a third end and a fourth end opposite to the third end on a cross-section parallel to the lower guide plate, the needle body of the second probe further comprises a fifth end and a sixth end opposite to the fifth end on a cross-section parallel to the lower guide plate, and a connection line connecting the third end and the fourth end and a connection line connecting the fifth end and the sixth end forms an acute angle therebetween.

6. The probe card device of claim 1, wherein the needle body of each of the plurality of probes has a central point on a cross-section parallel to the lower guide plate, and a polyline connecting the central points of the plurality of needle bodies forms a M-shape.
